(19) United States
(12) Patent Application Publication
(10) Pub. No.: US 2004/0139999 A1
(43) Pub. Date: Jul. 22, 2004

(54) Solar powered (photovoltaic) electro luminescent extruded lighting device

(76) Inventor: Luis Manuel Romo, Hoschton, GA (US)

Correspondence Address: LUIS M. ROMO, 56 BUCK TRAIL, HOSCHTON, GA, 30548, US

(21) Appl. No.: 10/735,173

(22) Filed: Dec. 13, 2003

Related U.S. Application Data
(60) Provisional application No. 60/433,274, filed on Dec. 16, 2002.

(51) Int. Cl. H01L 31/00

(52) U.S. Cl. 136/243; 136/244

(57) ABSTRACT

A flat-sectioned device that traps energy from the sun or any light source through the photovoltaic effect of it's upper surface material composition and releases light through the electroluminiscence effect of its lower surface material composition, all this carried or mounted on an extruded material pro file.

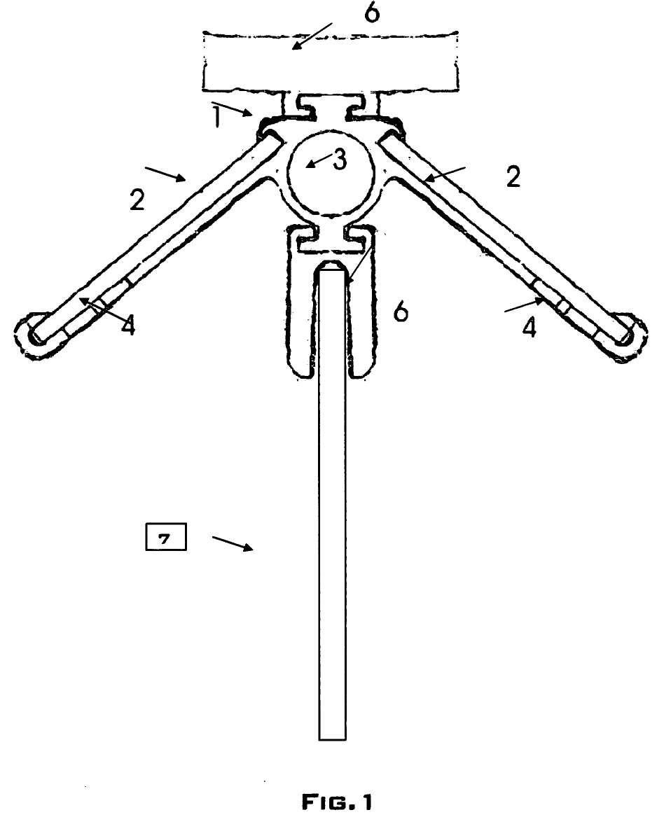

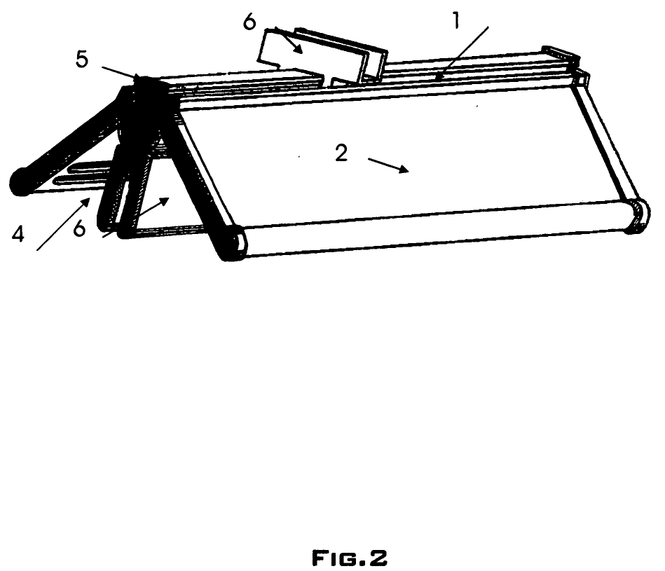

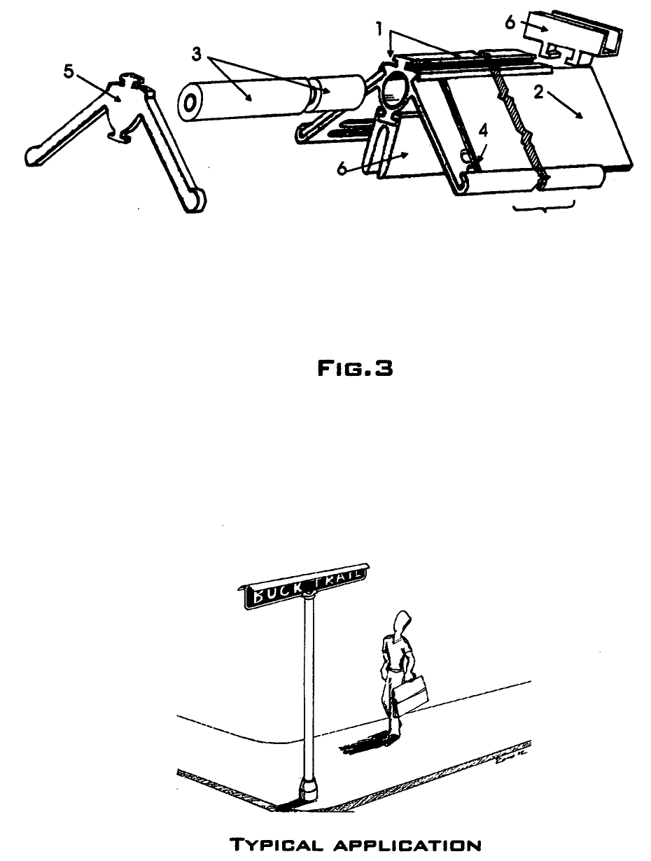

Although the principle described could use different types of photovoltaic and electro luminescent materials, our proto-type devices currently use a combination of “amorphous” (not crystalline) silicon photovoltaic cells which are deposited on one side of a plastic substrate by a photo printing process, combined with a layered phosphor crystal-based electroluminescent material deposited on a similar (to the photovoltaic side) plastic substrate.

The effect described, could utilize deactual manufacturing of the materials deposited on a same substrate or to different substrates that could be laminated together as part of the manufacturing or assembly process.

The result is or could be described as a “linear” (by the inch) substrate and it could be made into incremental lengths to fit into an extruded carrier or body of a light fixture to provide cordless illumination to commercial, institutional, architectural or municipal signage and structures.

### CROSS REFERENCE TO RELATED APPLICATIONS

A provisional application for patent of the same device was submitted and given the following application Ser. No. 60/433,274

Filing Date: Dec. 16, 2002.

Confirmation Number: 8507

Customer Number: 30176

### STATEMENT REGARDING FED SPONSORED R&D

None

### SEQUENCE LISTING

None

### BACKGROUND OF INVENTION

This invention is concerned with the double conversion of light or photons into electricity, storage of it and the converting of electricity back into photons.

While the described conversion was technically previously possible, this invention relates to achieving said conversion using a double surfaced, (upper and lower) combination or technologies, said technologies are arranged in an extruded, laminated and-or linearly produced components, to illuminate signs or any graphically reproduced information board.

### SUMMARY OF INVENTION

Solar Powered (Photovoltaic)-Electro Luminescent Extruded Device.

The present invention application is to provide grid-less powered illumination by combining the results of three physical material effects:

photo-voltaic materials,

electro-luminescent materials and

formed-by-extrusion materials.

The extruded carrier of the body of the fixture could be either made of aluminum or plastic on a technically similar process (extrusion) however, this invention in some of its applications, uses the transparency of the plastic (polycarbonate or similar) to conceal a combination of photovoltaic and electroluminescent “tape” or linear material under its extruded shape and therefore, it provides with a weather-proof performance of the device. The conversion of solar light into “night” light is controlled by an electronic components containing:

photo cell or light measuring devices,

batteries or “energy storage units” and

a circuitry or “inverter driver” that raises the voltage from the storage units into the higher voltage-minimum amperage which IB required to produce the electro luminescence effect.

We claim:

1. The use of photovoltaic and electroluminescent materials deposited on different planes of the same solid or laminated substrate.

2. The use of such materials combination in modular and incremental lengths.

3. The carrying or containing of the photovoltaic-electro luminescent materials in linear form by the use of translucent or transparent materials.

4. The manufacturing advantage of combining two linearly produced materials and structures to custom match the dimensional requirments of the device applications. (cut to length)

5. The installation versatility of the combinations: top-flat or top finned electronic control box to receive one or more similar fixtures in a cross stacking arrangements at no customized cost.

6. The structural combination of the different described elements into a clean-energy-environmental-friendly illumination system.

7. The combined and or individual advantage of each one of the elements of this description in similar applications but different fields, i.e.: agricultural, medical, automotive, industrial, telecommunications, aero-space et. al.
